(19) United States
(12) Patent Application Publication
(10) Pub. No.: US 2026/0039228 A1
(43) Pub. Date: Feb. 5, 2026

(54) ELECTROSTATIC CHUCK CLAMPING SYNCHRONIZATION

(71) Applicant: Advanced Energy Industries, Inc., Denver, CO (US)

(72) Inventors: Kevin Franciszek Mienta, Loveland, CO (US); Denis Shaw, Fort Collins, CO (US)

(21) Appl. No.: 18/794,745

(22) Filed: Aug. 5, 2024

(51) Int. Cl. H02N 13/00; H01L 21/683

(52) U.S. Cl. CPC H02N 13/00; H01L 21/6833

(57) ABSTRACT

Synchronization of electrostatic chuck (ESC) voltage with bias power pulses. In one aspect, an apparatus includes an interface configured to receive a synchronization signal indicating a change of power level of pulses output to a plasma chamber, and a controller configured to direct an electrostatic chuck (ESC) power supply to adjust a voltage level of a clamping voltage based on the synchronization signal.

### BACKGROUND

### Field of the Disclosure

The present disclosure relates generally to plasma processing. More specifically, but without limitation, the present disclosure relates to controlling an electrostatic chuck power supply to clamp a substrate for plasma processing.

### Background

An electrostatic chuck (ESC) physically supports and holds a semiconductor wafer or substrate during plasma processing. The ESC typically includes a pedestal, or ceramic plate, that provides a stable platform for the wafer. Additionally, the ESC includes electrodes embedded in the pedestal that generate an electrostatic holding force to clamp the wafer on the pedestal. The electrostatic force is generated from a clamping voltage provided by an ESC power supply. A typical plasma processing system applies a single, constant clamping voltage during processing to impart a constant electrostatic force for holding the wafer in place.

### SUMMARY

An aspect may be characterized as an apparatus including an interface configured to receive a synchronization signal indicating a change of power level of pulses output to a plasma chamber, and a controller configured to direct an electrostatic chuck (ESC) power supply to adjust a voltage level of a clamping voltage based on the synchronization signal.

Another aspect may be characterized as a method including applying a first clamping voltage at an output node of an electrostatic chuck (ESC) power supply, receiving a synchronization signal indicating a change of power level of pulses output to a plasma chamber, and applying a second clamping voltage at the output node based on the synchronization signal, the second clamping voltage being different in magnitude than the first clamping voltage.

Yet another aspect may be characterized as a non-transient computer-readable storage medium having instructions embodied thereon, the instructions are executable by a processor and/or capable of programming a field programmable gate array, the instructions including instructions for: applying a first clamping voltage at an output node of an electrostatic chuck (ESC) power supply, receiving a synchronization signal indicating a change of power level of pulses output to a plasma chamber, and applying a second clamping voltage at the output node based on the synchronization signal, the second clamping voltage being different in magnitude than the first clamping voltage.

Another aspect may be characterized as a plasma processing system, including an electrostatic chuck (ESC) power supply configured to apply and modify a clamping voltage to an electrostatic chuck (ESC) to modify an electrostatic force between the ESC and a wafer within a plasma processing chamber. The system also includes at least one controller configured to: synchronize the ESC power supply with a radio frequency (RF) generator during a first processing step to produce a first electrostatic force between the ESC and the substrate while the RF generator is producing a first pulsed power; and synchronize the ESC power supply with the RF generator during a second processing step to produce a second electrostatic force between the ESC and the substrate while the RF generator is producing a second pulsed power, wherein the second electrostatic force is different in magnitude than the first electrostatic force.

Still another aspect may be characterized as a method including applying a first radio frequency (RF) power pulse to a plasma processing chamber with an RF generator, and applying, during the first RF power pulse, a first clamping voltage to an electrostatic chuck (ESC) to produce a first electrostatic chucking force between the ESC and a substrate. The method also includes applying a second RF power pulse to the plasma processing chamber with the RF generator, wherein the second RF power pulse is different in magnitude than the first RF power pulse, and applying, during the second RF power pulse, a second clamping voltage to the ESC to produce a second electrostatic chucking force between the ESC and the substrate, wherein the second electrostatic chucking force is different in magnitude than the first electrostatic chucking force.

### BRIEF DESCRIPTION OF THE DRAWINGS

FIG. 1 is a block diagram of a plasma processing system in accordance with an embodiment of this disclosure.

FIG. 2 is a flowchart illustrating a method of clamping a substrate for plasma processing in an example embodiment.

FIG. 3 illustrates a first graph of a pulsing sequence output by a bias generator and a second graph of a synchronized clamping voltage according to an example embodiment.

FIG. 4 is a block diagram of an ESC power supply in accordance with an embodiment of this disclosure.

FIG. 5 is a block diagram of a synchronization controller in accordance with an embodiment of this disclosure.

FIG. 6 is a flowchart illustrating a method of clamping a substrate for plasma processing in another example embodiment.

FIG. 7 is a flowchart illustrating a method of clamping a substrate for plasma processing in yet another example embodiment.

FIG. 8 is a block diagram depicting physical components of a controller that may be utilized to realize control aspects disclosed herein.

### DETAILED DESCRIPTION

Aspects herein relate to improving wafer stability during the wafer fabrication process. Plasma processing systems increasingly use bias power pulsing techniques to control ion energy. However, each new bias power level may affect or change plasma conditions, causing variation in the wafer clamping force despite using a constant clamping voltage output to the chuck. Techniques herein relate to generating a new chucking voltage during each new bias power level to effectuate a constant wafer clamping force. This prevents the wafer from chucking and un-chucking from the pedestal at a high frequency during plasma processing with bias pulsing, and the improved stability of the wafer improves the precision of the plasma process such as plasma etching.

The following modes, features or aspects, given by way of example only, are described in order to provide a more precise understanding of the subject matter of several embodiments.

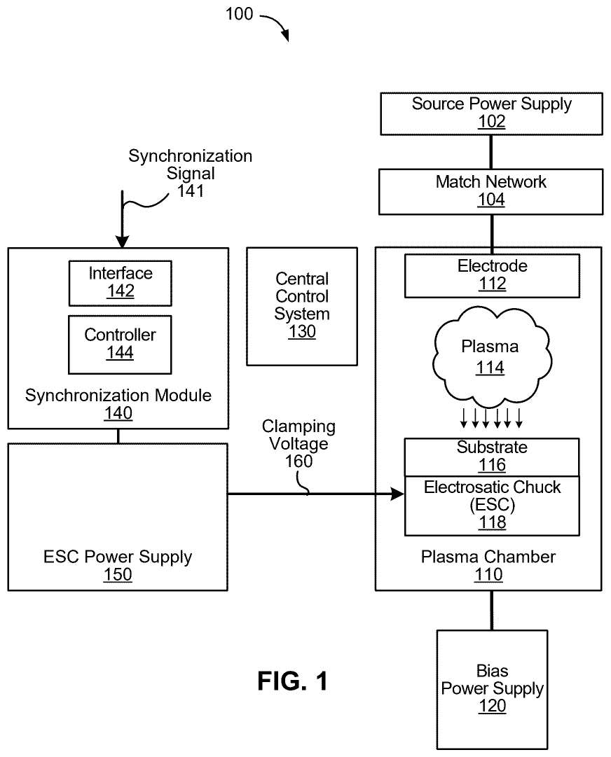

FIG. 1 is a block diagram of a plasma processing system 100 in accordance with an embodiment of this disclosure. Plasma processing system 100 is an example system (e.g., deposition or etch system) in which an electrostatic chuck (ESC) power supply 150 may be controlled to synchronize with a bias power supply 120. In general, source power supply 102 provides power (e.g., radio frequency (RF) power) via a match network 104 to a plasma chamber 110 to ignite and sustain a plasma 114. Plasma chamber 110 includes one or more electrodes 112 configured to generate plasma 114 from the source power. Within plasma chamber 110, a substrate 116 (e.g., silicon wafer) is supported or held by an electrostatic chuck (ESC) 118. Ions and electrons of plasma 114 react with and modify the surface of substrate 116 through processes such as etching or deposition.

ESC power supply 150 is electrically coupled with ESC 118 and configured to generate and apply a clamping voltage 160 to ESC 118. From clamping voltage 160, ESC 118 generates electrostatic force that holds substrate 116 in place on ESC 118 during plasma processing. In some embodiments, ESC 118 includes a pedestal (e.g., ceramic plate) with one or more electrodes (not shown) embedded within the pedestal, and the electrode(s) are electrically coupled with ESC power supply 150 to generate electrostatic forces from clamping voltage 160.

Bias power supply 120 is configured to generate and apply power to ESC 118 to control the energy of ions striking substrate 116 during plasma processing. The bias power applied to ESC 118 is configured to create an electric field between plasma 114 and substrate 116. The electrical potential difference between plasma 114 and substrate 116 is referred to as substrate voltage, and the magnitude of this voltage determines the kinetic energy of ions of plasma 114 striking the surface of substrate 116. Substrate voltage also affects the ion energy distribution at the surface of substrate 116 which is a factor in the uniformity and quality of plasma processing results. In some embodiments, bias power supply 120 generates and applies radio frequency (RF) power. In other embodiments, bias power supply 120 generates and applies power outside the RF domain.

Bias power supply 120 may pulse power for enhanced control over the ion energy distribution. By varying a pulse parameter (e.g., power level), different etch profiles may be achieved, allowing for more flexible and tunable processes. In multi-level pulsing, for example, a pulsing sequence may include applying a high power level for a few microseconds, followed by applying a low (e.g., non-zero) power level for a few microseconds. This pulsing pattern may help control the etch rate, profile, and uniformity as compared to applying continuous bias power at a single, constant voltage level.

Although bias pulsing is beneficial for several reasons, each new bias power level may change plasma conditions which may in turn unintentionally alter the wafer clamping force. Conventionally, plasma processes set the clamping voltage to a single, constant value for the duration of processing as it is thought to impart a constant stabilizing force on the wafer. However, each new bias pulse may undesirably strengthen or weaken the electrostatic force, and the wafer may become over-clamped or under-clamped during bias pulsing despite the constant clamping voltage. Over-clamping can damage the wafer or make it difficult to remove from the chuck when the plasma process is complete. Under-clamping can cause poor thermal transfer from the wafer to the chuck and may also damage fragile features during some processes such as plasma etching.

To address these issues, plasma processing system 100 is enhanced with a synchronization module 140 configured to synchronize the clamping voltage 160 with bias pulsing changes. Synchronization module 140 includes an interface 142 configured to receive a synchronization signal 141 indicating a change of power level of pulses (e.g., RF pulses) output to plasma chamber 110 for biasing substrate 116. Synchronization module 140 further includes a controller 144 configured to direct ESC power supply 150 to adjust a voltage level of clamping voltage 160 based on synchronization signal 141. Advantageously, synchronization module 140 enables modifying clamping voltage 160 to change in synchronization with changes in bias pulses so that the electrostatic clamping force between ESC 118 and substrate 116 is constant or substantially constant throughout the plasma process while using different bias pulse levels.

Functions and components of synchronization module 140 may reside in a stand-alone device or system of plasma processing system 100 as shown in FIG. 1. Alternatively or additionally, synchronization module 140 may by wholly or partially integrated with other components of plasma processing system 100 such as ESC power supply 150, bias power supply 120, source power supply 102, and/or a central control system 130. Generally, central control system 130 may coordinate various subsystems, manage process parameters, and provide interfaces for user interaction and data management. In some embodiments, central control system 130 includes a master clock or generator to produce timing signals, such as synchronization signal 141, for coordinating the operation of components of plasma processing system 100. Central control system 130 may communicate synchronization signal 141 to each relevant component, including synchronization module 140, ESC power supply 150, bias power supply 120, and/or source power supply 102.

Alternatively or additionally, synchronization signal 141 may be generated and/or communicated by bias power supply 120. For instance, bias power supply 120 may generate and send synchronization signal 141 in response to applying a different power level to ESC 118, and synchronization signal 141 may trigger synchronization module 140 and/or ESC power supply 150 to modify clamping voltage 160 accordingly. Alternatively, bias power supply 120 may communicate synchronization signal 141 in advance of, or prior to, applying a different power level to ESC 118. In such embodiments, synchronization signal 141 may include timing information, or an upcoming time, for applying a different power level, and synchronization module 140 may delay triggering a voltage level change of clamping voltage according to the upcoming time. Synchronization signal 141 may be transmitted via dedicated communication lines (e.g., a direct connection from bias power supply 120 to synchronization module 140 and/or ESC power supply 150) and/or a central control system 130 that manages clock/timing signals.

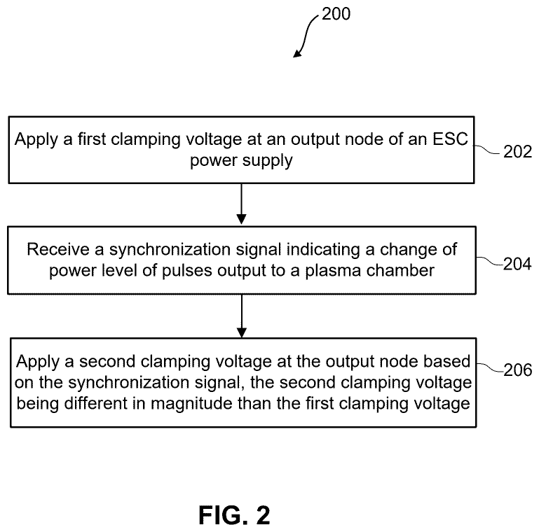

FIG. 2 is a flowchart illustrating a method 200 of clamping a substrate for plasma processing in an example embodiment. The steps of the method are described with reference to the plasma processing system 100 of FIG. 1, but those skilled in the art will appreciate that the method may be performed in other systems. The steps of the flowcharts described herein are not all inclusive, may include other steps not shown, and may be performed in an alternative order.

In step 202, ESC power supply 150 applies a first clamping voltage at an output node. In step 204, synchronization module 140 receives synchronization signal 141 indicating a change of power level of pulses output to plasma chamber. In step 206, ESC power supply 150 applies a second clamping voltage at the output node based on synchronization signal 141, the second clamping voltage being different in magnitude than the first clamping voltage.

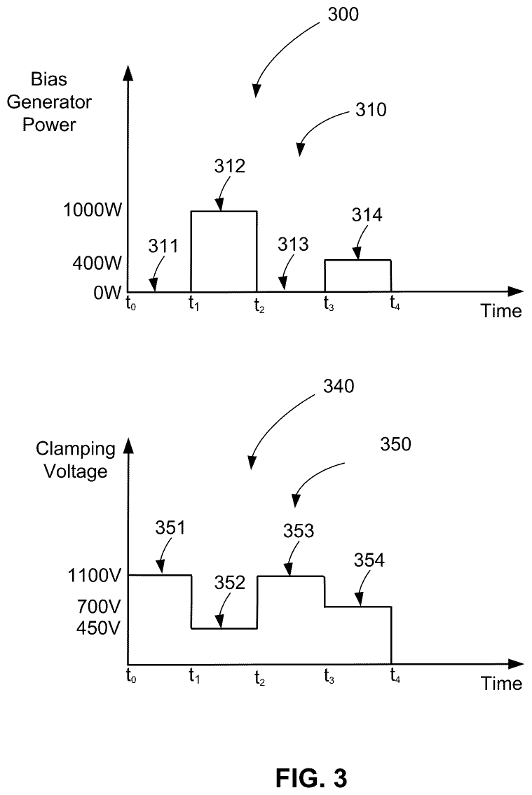

FIG. 3 illustrates a first graph 300 of a pulsing sequence 310 output by a bias generator and a second graph 340 of a synchronized clamping voltage 350 according to an example embodiment. Suppose, for this example, pulsing sequence 310 (e.g., RF pulsing sequence) includes a low power pulse 311 (e.g., off state or 0 watts (W)) from time t₀ to t₁, followed by a high power pulse 312 (e.g., 1,000 W) from time t₁ to t₂, followed by another low power pulse 313 from time t₂ to t₃, followed by a medium power pulse 314 (e.g., 400 W) from time t₃ to t₄. Pulsing sequence 310 may be periodic and repeating to help achieve a desired processing outcome by controlling the ion energy and flux during an etching or deposition process.

Further suppose that synchronization module 140 directs the ESC power supply 150 to output synchronized clamping voltage 350 to neutralize the effect bias pulsing has on electrostatic chucking forces. In this example, during the low power pulse from time t₀ to t₁, ESC power supply 150 outputs a high clamping voltage 351 (e.g., 1,100 volts (V)). During the high power pulse 312 from time t₁ to t₂, ESC power supply 150 outputs a low clamping voltage 352 (e.g., 450 V). From time t₂ to t₃, ESC power supply 150 outputs another high clamping voltage 353. And, during the medium power pulse 314 from time t₃ to t₄, ESC power supply 150 outputs a medium clamping voltage 354 (e.g., 700 V).

Here, the high clamping voltage states may increase the electrostatic clamping force applied by ESC 118 to substrate 116 to compensate for the unintentional decrease in electrostatic force caused by the low bias power pulses. Similarly, since a high pulse state from time t₁ to t₂ may alter plasma conditions to cause an increase in electrostatic force, synchronization module 140 may direct ESC power supply 150 to offset or counterbalance this effect by applying a low voltage level or pulse during the same period from time t₁ to t₂. The result is that, during pulsing sequence 310 from time t₀ to t₄, the clamping voltage level adjusts in real time or near real time with each change in bias power level to maintain a constant wafer clamping force from time t₀ to t₄, improving plasma processing precision and outcomes.

Synchronization module 140 may be configured to accurately determine the appropriate voltage level for ESC power supply 150 to apply as further described below. It will be appreciated that the example values described with respect to FIG. 3 are provided for discussion purposes and that alternative values, sequences, and pulse types may apply. Additionally, the example described with respect to FIG. 3 assumes, for instance, that high bias power values tend to amplify the electrostatic force and that low bias power values tend to weaken the electrostatic force. However, it will be appreciated that the relationship between bias pulses and electrostatic force may be influenced by numerous variables, such as chamber configurations and type of gas, and that an inverse relationship may apply. Similarly, the proportional relationship between magnitudes of bias power, clamping voltage, and/or electrostatic force may also vary according to individual system configurations. To that end, synchronization module 140 may be configured to determine the appropriate voltage level for ESC power supply 150 to apply based on the individual characteristics of the plasma system it is operating with.

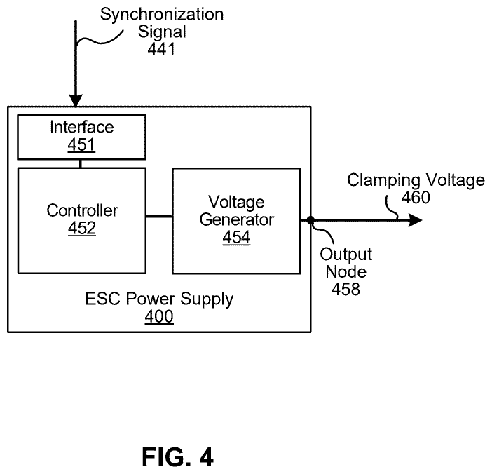

FIG. 4 is a block diagram of an ESC power supply 400 in accordance with an embodiment of this disclosure. In some embodiments, the synchronization functions described herein are integrated with ESC power supply 400 which includes an interface 451, controller 452, and voltage generator 454. Interface 451 may receive a synchronization signal 441 via a wired or wireless connection from another component of a plasma system, such as a bias power generator. Controller 452, which may be communicatively coupled with interface 451 and voltage generator 454, may determine or calculate a voltage level of a clamping voltage 460 based on synchronization signal 441, and direct voltage generator 454 to adjust or output the clamping voltage 460 to output node 458. Output node 458 may be electrically coupled with an electrostatic chuck (e.g., ESC 118).

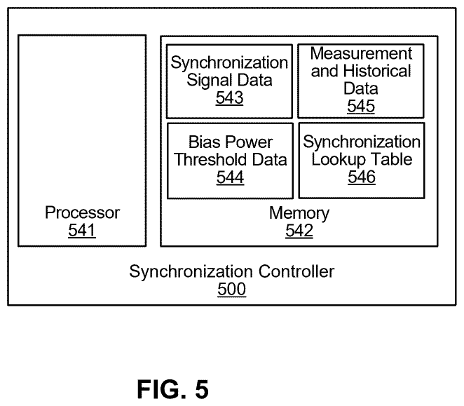

FIG. 5 is a block diagram of a synchronization controller 500 in accordance with an embodiment of this disclosure. Synchronization controller 500 may be implemented as or with controller 144 of synchronization module 140, controller 452 of ESC power supply 400, a controller of bias power supply 120, and/or a controller of central control system 130. Synchronization controller 500 may include a processor 541 and memory 542 which function together to calculate or determine voltage levels of the clamping voltage.

Processor 541 may accurately determine the appropriate clamping voltage level to apply based on various inputs such as synchronization signal data 543, bias power threshold data 544, and/or measurement and historical data 545 stored in memory 542. Synchronization signal data 543 may include characteristics of a received synchronization signal. For example, synchronization signal data 543 may include a power value of a bias pulse being applied, an upcoming time for beginning application of the pulse (e.g., to synchronize beginning application of adjusted clamping voltage via a common clock time between components), and/or a duration of applying the pulse. In some embodiments, a received synchronization signal includes data for synchronization with a series of pulses or one or more sequences of pulses to be applied.

In some embodiments, memory 542 stores a synchronization lookup table 546 that maps one or more input values to corresponding voltage levels of the clamping voltage and/or timing for applying the clamping voltage. For example, processor 541 may input a bias power level value received in a synchronization signal into synchronization lookup table 546 to determine the associated clamping voltage level for stabilizing electrostatic clamping force. In another example, processor 541 may input a received identifier for a pulse or pulse sequence to retrieve one or more clamping voltage values for applying to a chuck. Synchronization lookup table 546 may be manually updated or automatically updated over time based on processing outcomes, characteristics, and/or measurements.

Synchronization controller 500 may also receive and store measurement and historical data 545. Chamber gas flow data is one example of measurement data that synchronization controller 500 may monitor and use as feedback to adjust the clamping voltage. For example, one or more mass flow controllers may be included in the chamber assembly which report the pressure and flow rate of helium gas. The helium may move through the electrostatic chuck and disperse through a grid of small holes at the top of the electrostatic chuck underneath the wafer. If the wafer clamps harder to the chuck, less helium gas can travel underneath it, and as the wafer unclamps the helium gas can flow easier. Therefore, as plasma conditions change, the movement of the wafer may be detected by a change in the helium flow as detected by the one or more mass flow controllers. By measuring and storing helium flow data, synchronization controller 500 may estimate or calculate an electrostatic clamping force on the wafer, and thus may determine an adjusted clamping voltage to apply based on helium flow data feedback.

In some embodiments, synchronization controller 500 calculates or derives the clamping voltage level with a computational model to predict the voltage value(s) to effectuate a desired clamping force based on various input parameters. For example, synchronization controller 500 may employ machine learning functions to determine or predict the appropriate clamping voltage level. By training on historical data (e.g., measurement and historical data 545) and learning from patterns and trends, synchronization controller 500 may adapt its voltage determinations to ensure accurate and efficient clamping voltage application. Alternatively or additionally, synchronization controller 500 may employ curve fitting techniques, regression analysis techniques, or other model-based voltage determination techniques to determine the clamping voltage.

Synchronization controller 500 may also receive and store thresholds or instructions for processing/analyzing synchronization signals. For instance, bias power threshold data 544 may indicate a minimum amplitude change between adjacent bias pulses to trigger synchronization action. If the amplitude change is small, or below a threshold, the corresponding change in plasma conditions may also be small such that adjusting the clamping force is unnecessary. Further details are described below.

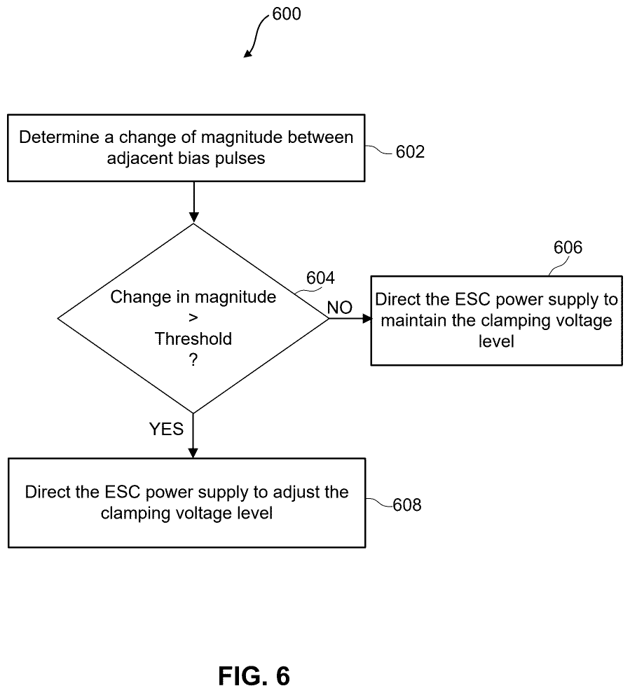

FIG. 6 is a flowchart illustrating a method 600 of clamping a substrate for plasma processing in another example embodiment. The steps of the method are described with reference to the plasma processing system 100 of FIG. 1, but those skilled in the art will appreciate that the method may be performed in other systems.

In step 602, controller 144 determines a change of magnitude between adjacent bias pulses. In step 604, controller 144 determines whether the change of magnitude is greater than a threshold. If not, method 600 proceeds to step 606 and controller 144 directs ESC power supply 150 to maintain the clamping voltage level or otherwise refrains from adjusting the clamping voltage. Otherwise, if the change of magnitude is greater than the threshold, method 600 proceeds to step 608 and controller 144 directs ESC power supply 150 to adjust the clamping voltage level.

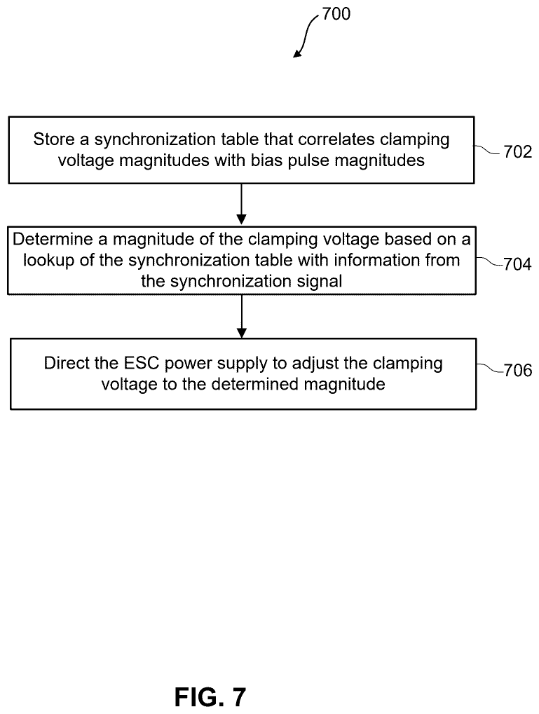

FIG. 7 is a flowchart illustrating a method 700 of clamping a substrate for plasma processing in yet another example embodiment. The steps of the method are described with reference to the plasma processing system 100 of FIG. 1, but those skilled in the art will appreciate that the method may be performed in other systems.

In step 702, controller 144 stores a synchronization table that correlates clamping voltage magnitudes with bias pulse magnitudes. In step 704, controller 144 determines a magnitude of the clamping voltage based on a lookup of the synchronization table with information from the synchronization signal 141. In step 706, controller 144 directs ESC power supply 150 to adjust the clamping voltage level to the determined magnitude.

The various illustrative logical blocks, modules, and circuits described in connection with the embodiments disclosed herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC.

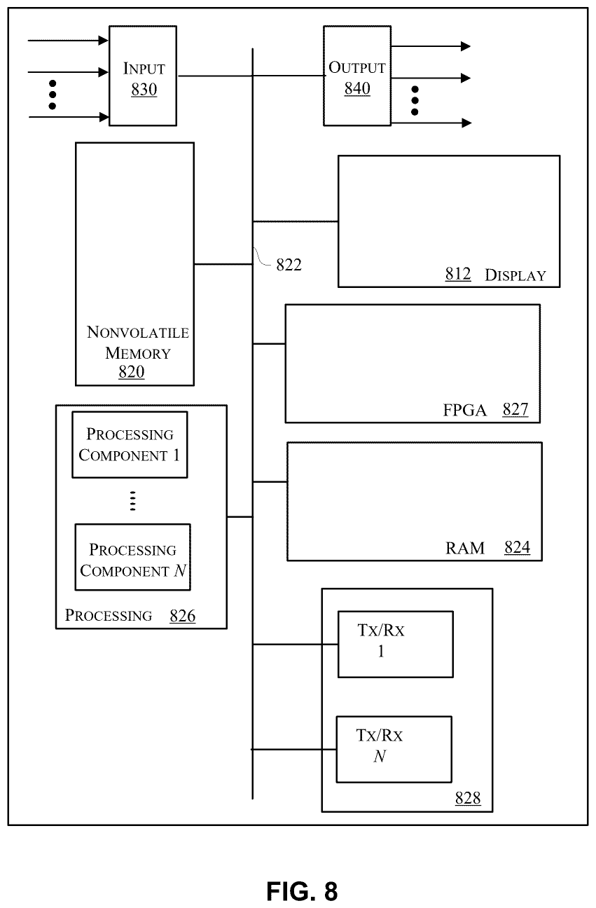

Many embodiments and methods described herein may be realized using a processor in connection with processor executable instructions and a field programmable gate array (programmed by hardware description language instructions). In some embodiments, the FPGA is used for high-speed processing and control, including switching control, measurement, pulsing, and multi-level operation while a processor is utilized for other lower-speed processing. Referring to FIG. 8 for example, shown is a block diagram depicting physical components of a controller that may be utilized to realize control aspects disclosed herein.

As shown, in this embodiment a display 812 and nonvolatile memory 820 are coupled to a bus 822 that is also coupled to random access memory (“RAM”) 824, a processing portion (which includes N processing components) 826, a field programmable gate array (FPGA) 827, and a transceiver component 828 that includes N transceivers. Although the components depicted in FIG. 8 represent physical components, FIG. 8 is not intended to be a detailed hardware diagram; thus, many of the components depicted in FIG. 8 may be realized by common constructs or distributed among additional physical components. Moreover, it is contemplated that other existing and yet-to-be developed physical components and architectures may be utilized to implement the functional components described with reference to FIG. 8.

This display 812 generally operates to provide a user interface for a user, and in several implementations, the display is realized by a touchscreen display. In general, the nonvolatile memory 820 is non-transitory memory that functions to store (e.g., persistently store) data and processor-executable code (including executable code that is associated with effectuating the methods described herein). In some embodiments for example, the nonvolatile memory 820 includes bootloader code, operating system code, file system code, and non-transitory processor-executable code to facilitate the execution of a method or functions described herein for controlling a bias power based on plasma impedance. Alternatively or additionally, nonvolatile memory 820 may receive and store thresholds or instructions for processing/extracting impedance indicators for feedback control.

In many implementations, the nonvolatile memory 820 is realized by flash memory (e.g., NAND or ONENAND memory), but it is contemplated that other memory types may be utilized as well. Although it may be possible to execute the code from the nonvolatile memory 820, the executable code in the nonvolatile memory is typically loaded into RAM 824 and executed by one or more of the N processing components in the processing portion 826. The N processing components in connection with RAM 824 generally operate to execute the instructions stored in nonvolatile memory 820 to enable execution of the algorithms and functions disclosed herein. It should be recognized that several algorithms or functions are disclosed herein, but some of these algorithms or functions are not represented in flowcharts. Processor-executable code to effectuate methods described herein may be persistently stored in nonvolatile memory 820 and executed by the N processing components in connection with RAM 824. As one of ordinarily skill in the art will appreciate, the processing portion 826 may include a video processor, digital signal processor (DSP), micro-controller, graphics processing unit (GPU), or other hardware processing components or combinations of hardware and software processing components (e.g., an FPGA or an FPGA including digital logic processing portions). In addition, or in the alternative, non-transitory FPGA-configuration-instructions may be persistently stored in nonvolatile memory 820 and accessed (e.g., during boot up) to configure a field programmable gate array (FPGA) to implement the algorithms disclosed herein. In some embodiments, the processing portion 826 (in connection with processor-executable instructions stored in the nonvolatile memory 820) are used to realize the controllers disclosed herein, and functions of the controller may reside in an ESC power supply, a bias supply, and/or other components of a plasma processing system. But the FPGA 827 may also be used to implement these functions.

The input component 830 may receive synchronization signals, and the output component 840 may provide one or more analog or digital signals to effectuate clamping voltage adjustment. The output component 840 may also control one or more aspects of the power supplies described herein. The depicted transceiver component 828 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

As will be appreciated by one skilled in the art, aspects of the present disclosure may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present disclosure may take the form of a computer program product embodied in one or more computer readable medium(s) having computer readable program code embodied thereon.

What is claimed is:

1. An apparatus, comprising:
an interface configured to receive a synchronization signal indicating a change of power level of bias pulses output to a plasma chamber; and
a controller configured to direct an electrostatic chuck (ESC) power supply to adjust a voltage level of a clamping voltage based on the synchronization signal.

2. The apparatus of claim 1, wherein:
the controller is configured to direct the ESC power supply to pulse the clamping voltage to different voltage levels in synchronization with different power levels of the bias pulses.

3. The apparatus of claim 1, further comprising:
memory configured to store a synchronization table that correlates clamping voltage magnitudes with bias pulse magnitudes;
wherein the controller is configured to determine a magnitude of the clamping voltage based on a lookup of the synchronization table with information from the synchronization signal, and to direct the ESC power supply to adjust the clamping voltage to the determined magnitude.

4. The apparatus of claim 1, wherein:
the controller is configured to determine a change of magnitude between adjacent bias pulses, to compare the change of magnitude to a threshold, to direct the ESC power supply to maintain the voltage level if the change of magnitude is less than the threshold, and to direct the ESC power supply to adjust the voltage level if the change of magnitude is greater than the threshold.

5. The apparatus of claim 1, wherein:
the controller is configured to receive the synchronization signal from a bias power supply.

6. The apparatus of claim 1, wherein:
the ESC power supply is configured to apply the clamping voltage to a chuck to clamp a wafer during plasma processing.

7. The apparatus of claim 6, wherein:
the controller is configured to direct the ESC power supply to adjust the voltage level of the clamping voltage to maintain a constant clamping force between the chuck and the wafer during application of different power levels of the bias pulses to the plasma chamber.

8. The apparatus of claim 1, wherein:
the controller is integrated with the ESC power supply.

9. The apparatus of claim 1, wherein:
the controller is communicatively coupled with a voltage generator of the ESC power supply, the voltage generator configured to output the clamping voltage to an electrostatic chuck.

10. A method comprising:
applying a first clamping voltage at an output node of an electrostatic chuck (ESC) power supply;
receiving a synchronization signal indicating a change of power level of bias pulses output to a plasma chamber; and
applying a second clamping voltage at the output node based on the synchronization signal, the second clamping voltage being different in magnitude than the first clamping voltage.

11. The method of claim 10, further comprising:
pulsing the clamping voltage to different voltage levels in synchronization with different power levels of the bias pulses.

12. The method of claim 10, further comprising:
storing a synchronization table that correlates clamping voltage magnitudes with bias pulse magnitudes;
determining a magnitude of the clamping voltage based on a lookup of the synchronization table with information from the synchronization signal; and
adjusting the clamping voltage to the determined magnitude.

13. The method of claim 10, further comprising:
determining a change of magnitude between adjacent bias pulses;
comparing the change of magnitude to a threshold;
maintaining the voltage level if the change of magnitude is less than the threshold; and
adjusting the voltage level if the change of magnitude is greater than the threshold.

14. The method of claim 10, further comprising:
adjusting the voltage level of the clamping voltage to maintain a constant clamping force between a chuck and a wafer during application of different power levels of the bias pulses to the plasma chamber.

15. A non-transitory computer-readable storage medium having instructions embodied thereon, the instructions are executable by a processor and/or capable of programming a field programmable gate array, the instructions comprising instructions for:
applying a first clamping voltage at an output node of an electrostatic chuck (ESC) power supply;
receiving a synchronization signal indicating a change of power level of bias pulses output to a plasma chamber; and
applying a second clamping voltage at the output node based on the synchronization signal, the second clamping voltage being different in magnitude than the first clamping voltage.

16. The non-transitory computer-readable storage medium of claim 15, wherein the instructions comprise instructions for:
pulsing the clamping voltage to different voltage levels in synchronization with different power levels of the bias pulses.

17. The non-transitory computer-readable storage medium of claim 15, wherein the instructions comprise instructions for:
storing a synchronization table that correlates clamping voltage magnitudes with bias pulse magnitudes;
determining a magnitude of the clamping voltage based on a lookup of the synchronization table with information from the synchronization signal; and
adjusting the clamping voltage to the determined magnitude.

18. The non-transitory computer-readable storage medium of claim 15, wherein the instructions comprise instructions for:
determining a change of magnitude between adjacent bias pulses;
comparing the change of magnitude to a threshold;
maintaining the voltage level if the change of magnitude is less than the threshold; and
adjusting the voltage level if the change of magnitude is greater than the threshold.

19. The non-transitory computer-readable storage medium of claim 15, wherein the instructions comprise instructions for:
adjusting the voltage level of the clamping voltage to maintain a constant clamping force between a chuck and a wafer during application of different power levels of the bias pulses to the plasma chamber.

20. The non-transitory computer-readable storage medium of claim 15, wherein the instructions comprise instructions for:
applying the clamping voltage to a chuck to clamp a wafer during plasma processing.
